(19) United States
(12) Patent Application Publication
(10) Pub. No.: US 2021/0021228 A1
(43) Pub. Date: Jan. 21, 2021

(54) SILICON BASED MID-IR SUPER ABSORBER USING HYPERBOLIC METAMATERIAL

(71) Applicant: The American University in Cairo, New York, NY (US)

(72) Inventors: Mohamed Swillam, New Cairo (EG); Ahmed M. Mahmoud, New Cairo (EG); Mai Desouky, New Cairo (EG)

(21) Appl. No.: 17/065,329

(22) Filed: Oct. 7, 2020

Related U.S. Application Data
(63) Continuation of application No. 16/425,673, filed on May 29, 2019.
Application No. 16/425,673 is a continuation-in-part of application No. 16/244,778, filed on Jan. 10, 2019, now abandoned.
(60) Provisional application No. 62/615,690, filed on Jan. 10, 2018.

(51) Int. Cl. H02S 10/30; G02B 5/18; G02B 1/00

(52) U.S. Cl. CPC H02S 10/30; G02B 1/002; G02B 5/18

(57) ABSTRACT

A broadband hyperbolic metamaterial absorber is provided that includes a substrate layer, a plurality of N-doped silicon layers, a plurality of silicon layers, and a silicon grating layer, where the silicon grating layer includes a pattern of through-holes, where the through-holes have a diameter d, a height h, and a periodic separation distance a, where the plurality of N-doped silicon layers and the plurality of silicon layers are arranged in a stack of alternating layers of N-doped silicon layers and silicon layers disposed on the substrate layer, where the silicon grating layer is disposed on the stack of alternating layers of N-doped silicon layers and silicon layers.

### CROSS-REFERENCE TO RELATED APPLICATIONS

This application is a continuation of U.S. patent application Ser. No. 16/425,673 filed May 29, 2019 and hereby incorporated by reference in its entirety.

Application Ser. No. 16/425,673 is a continuation-in-part of U.S. patent application Ser. No. 16/244,778 filed Jan. 10, 2019, which is incorporated herein by reference.

Application Ser. No. 16/244,778 claims the benefit of U.S. Provisional Application 62/615,690 filed Jan. 10, 2018, which is incorporated herein by reference.

### FIELD OF THE INVENTION

The present invention relates generally to absorbers for energy harvesting. More particularly, the invention relates to a Silicon (Si) based mid IR super absorber.

### BACKGROUND OF THE INVENTION

Energy harvesting and handling is an important aspect required for several applications ranging from Microwave range ex: stealth application to near IR ex: thermal photovoltaic. Heat losses associated with electronic and electro-optical devices is a major drawback that affects the performance of electronic/photonic circuits. In order to control the thermal losses in electronic/photonic circuits, a CMOS compatible electromagnetic wave absorber is an ultimate requirement. Electromagnetic wave absorbers are classified into; i) single energy absorbers and ii) broadband absorbers (BBA). Single absorbers are single frequency absorbers, at certain wavelength, unity absorption could be realized when impedance is perfectly matched with the surrounding medium. On the other hand, BBA's can be realized through multiple ways in which one of these ways is using multiple resonators so that several absorption peaks can be coupled. Unfortunately, broadband absorbers based on coupled resonators results in increase in total thickness of the designed absorber. Other structures have been proposed which are relieved from the strict impedance matching requirement and demonstrated wide bandwidth operation. Among these absorbers are; porous Si absorbers, Si Nano wires, and metallic plasmonic particles. Even though these structures have shown high absorption values they encounter major drawbacks including bulkiness as in the case of Si nano wires, others may suffer instability over time as in the case of synthesized plasmonic metal particles.

Metamaterials are promising candidate for super absorbers (near unity absorbers) of smaller thickness. Metamaterials have gained increased attention over the past years after revisiting previous theoretical proposals on negative index medium. Now, metamaterials have extended their avenues to include applications in super focusing, sub-wavelength imaging and super absorption. Several studies showed that metamaterials could be used to achieve single and broadband absorption using specifically engineered metal/dielectric stacks, namely Hyperbolic Metamaterial (HMM). HMM is characterized by its anisotropic permittivity tensor components, where it behaves as a metal in one dimension (ε<0) and as a dielectric (ε>0) in the other dimension. This hyperboloid iso-frequency surface allows the HMM to exhibit unique optical and physical properties that cannot be found in any natural occurring materials. Among these properties is coupling of high propagation wave vectors which are evanescent in vacuum into propagating modes in the HMM. In addition, HMMs have an open/unbound hyperboloid dispersion which inherit them the property of having large photonic density of states. These pre-mentioned properties have made the HMMs widely investigated for absorption application. A study has shown that HMM could have reduced reflection when ITO nano particles scatter the incident field inside the HMM. Another theoretical study showed that surface roughening within the HMM layers could result in BBA. Many studies have reported BBA using trapezoidal-shaped HMMs. The tapered hyperbolic layers have slow light modes that enhance light confinement to the hyperbolic wave-guided tapers. Nevertheless, the control over fabrication of such structure is still a major challenge. Another design has been reported showing that introducing a hole grating on HMM can excite lossy modes of Bulk Plasmon Polaritons (BPPs) which can lead to broadband absorption. By designing a diffraction grating with proper dimension, the wave vectors of incident light can be coupled with the HMM wave vectors leading to near unity absorption. On the other hand, the CMOS compatible BBA absorber that is essential for harvesting thermal energy for on-chip applications is still of extreme importance nowadays. Another group has proposed a broadband mid IR Si based absorber in which BBA originated from free carrier absorption and plasmonic resonances. The structure, however, included an electrically large p-doped substrate in which the broadband behavior can be attributed.

What is needed is a single and broadband absorber in the mid IR wavelength range using a fully Si based HMM.

### SUMMARY OF THE INVENTION

To address the needs in the art, a broadband hyperbolic metamaterial absorber is provided that includes a substrate layer, a plurality of N-doped silicon layers, a plurality of silicon layers, and a silicon grating layer, where the silicon grating layer includes a pattern of through-holes, where the through-holes have a diameter d, a height h, and a periodic separation distance a, where the plurality of N-doped silicon layers and the plurality of silicon layers are arranged in a stack of alternating layers of N-doped silicon layers and silicon layers disposed on the substrate layer, where the silicon grating layer is disposed on the stack of alternating layers of N-doped silicon layers and silicon layers.

According to one aspect of the invention, the through-hole diameter d has a size in a range of 100 nm to 400 nm while a and h are fixed.

In another aspect of the invention, the through-hole height h has a size in a range of 100 nm to 600 nm while d and a are fixed.

In a further aspect of the invention, the substrate layer includes silicon, Ge, GaAs, or InAs.

According to one aspect of the invention, an absorption (A) of 0.95 is within a Mid IR wave length range from 3-8 μm.

### BRIEF DESCRIPTION OF THE DRAWINGS

FIGS. 1A-1F show (1A) a schematic drawing of the HMM device having 10 alternating layers of N-doped Si (light) and Si (dark), integrated with Si grating containing periodic air holes (dark). The period a is 500 nm, the height of hole is given by h while the diameter is given by d. The effective permittivities were defined such that ε_{∥} is along the x and z-axis while ε_{⊥} is along the y axis. (1B) shows parallel and perpendicular effective permittivity of N-doped Si/Si HMM using equations (1) and (2). (1C-1D)R, T and A (red) for bulk effective medium of N-doped Si/Si HMM, (1C) without Si grating, and (1D) with sub-hole Si grating. (1E) show silicon hole grating only and (1F) silicon grating on perfect reflector, according to the current invention.

FIGS. 2A-2F show the absorption spectrum for sub-hole Si grating on N-doped Si/Si HMM, (2A) d is fixed at 100 nm while h varies from 100 to 600 nm. (2B) d varies from 50 to 450 nm while h is fixed at 300 nm. Oblique incidence of angle 70 degrees was used for both cases (2A) and (2B). (2B) TM and TE modes at three angles of incidence (0, 30 and 70 degrees) were studied for grating of dimensions d=100 nm and h=300 nm. (2D) Color map showing absorption at different doping concentrations N_{d} (2E) reflection spectrum for uniform hole grating on HMM. Different angles of incidence from 0 to 70 degrees (2F) dispersion relation for doped Si/Si HMM N_{d} of 1×10²⁰ cm⁻³, according to the current invention.

FIGS. 3A-3B show the electric field distribution E² (V/m)² in XY plane for sub-hole Si grating of dimensions (d=100 nm and h=300 nm) on N-doped Si/Si HMM for wavelength (a) 12 μm and (b) 7 μm, according to the current invention.

FIGS. 4A-4C show a schematic drawing for BBA HMM. (4A) 10 alternating layers of N-doped Si (light) and Si (dark) HMM with multi height sub-hole Si grating (MHSG). The period a is 500 nm, d is 50 nm, t is 300 nm and h are taken to be; 100, 200, 300, 400, 500 and 600 nm. (4B)R, T and A for MHSG on N-doped Si/Si. (4C) Broad band absorption for MHSG. Absorption for MHSG on N-doped Si/Si HMM at oblique incidence from 0 to 40 degrees. R, T and A for MDSG on N-doped Si/Si HM at normal TM injection for grating of h 550 nm, according to the current invention.

FIGS. 5A-5D show the Electric field distribution E² (V/m)² for multi dimension sub-hole Si grating (MHSG) on N-doped Si/Si HMM at different wave lengths; (5A) 12 μm, (5B) 7 μm, (5C) 5.5 μm and (5D) 4.3 μm, according to the current invention.

FIG. 5E shows broad band absorption for MDSG. R, T and A for MDSG on N-doped Si/Si HM at normal TM injection for grating of h 550 nm, according to the current invention.

FIGS. 6A-6B show a schematic for BBA HMM. (6A) 10 alternating layers of N-doped Si/Si with multi diameters sub-hole Si grating (MDSG). Four holes of d 100, 200, 300 and 400 nm were chosen with a of 400 nm. (5B) Absorption at different grating heights h for MDSG on HMM: 350, 450, 550 and 650 nm, according to the current invention.

### DETAILED DESCRIPTION

Perfect absorbers are indispensable components for energy harvesting applications. While many absorbers have been proposed, they encounter inevitable drawbacks including bulkiness or instability over time. The urge for a CMOS compatible absorber that can be integrated for on-chip applications requires further investigation. The current invention demonstrates a Silicon (Si) based mid IR super absorber with absorption (A) reaching 0.948. In one embodiment, the structure is composed of multilayered N-doped Si/Si hyperbolic metamaterial (HMM) integrated with sub-hole Si grating. In another embodiment, the structure has a tunable absorption peak that can be tuned from 4.5 μm to 11 μm through changing the grating parameters. In further embodiments, the invention includes two grating designs integrated with N-doped Si/Si HMM that can achieve wide band absorption. The first grating design is based on Si grating incorporating different holes' height with hole separation distance (a) varying between 0.83 and 0.97 for wavelength from 5 μm to 7 μm. The second grating design is based on Si grating with variable holes' diameter (d); the latter shows broadband absorption with the maximum (A) reaching 0.97. Disclosed herein is that the structure is omnidirectional. In one aspect, the current invention is an all Si based absorber, which demonstrates a good candidate for thermal harvesting application.

Demonstrated herein is a mid-IR Si based super absorber of total thickness not exceeding 1 μm using HMM integrated with sub-hole Si grating. Single band absorption was achievable with (A) reaching 0.948. The invention is able to tune the absorption peak over the mid-IR range from 4.5 to 11 μm by either changing the grating hole's height or by changing the hole's diameter. The disclosure confirms that the invention is an omnidirectional and less-polarization dependent absorber. One embodiment has profound application in bio and chemical sensing mechanisms based upon tuning the single absorption peak of predesigned grating. Show herein is that BBA can be achieved by using an all Si based structure. The disclosed two grating designs, namely: Si grating with different holes' height and Si grating with different holes' diameter, both are integrated with the N-doped Si/Si HMM. Both designs have acquired BBA with maximum (A) reaching 0.97. For Metamaterial fabrication, standard chemical vapor deposition can be applied for Si layers deposition while ion beam irradiation can be used to dope the Si layers. For patterning both the periodic grating or the multiple diameters' hole grating, photolithography and deep reactive ion etching can be used. For grating of different hole heights', Nano imprint lithography can be used to pattern a stair case grating followed by photolithography and deep reactive ion etching. This absorber opens avenues for CMOS compatible energy harvesters for on chip purposes. The invention addresses the need for an on chip CMOS compatible energy harvesters.

Provided herein is a single and broadband absorber in the mid IR wavelength range using a fully Si based HMM. In one embodiment, the invention includes a sub-hole Si grating on top of N-doped Si/Si HMM. In another embodiment, the absorption peak can be widely and easily tuned by changing the dimensions of the grating (hole's diameter and hole's height) across the mid-IR range. In a further embodiment a two unit cell of sub-hole Si grating is integrated on N-doped Si/Si HMM to achieve broadband absorption reaching a maximum (A) of 0.97. These embodiments have minimal angle dependence, which is a very important requirement for efficient energy harvesting.

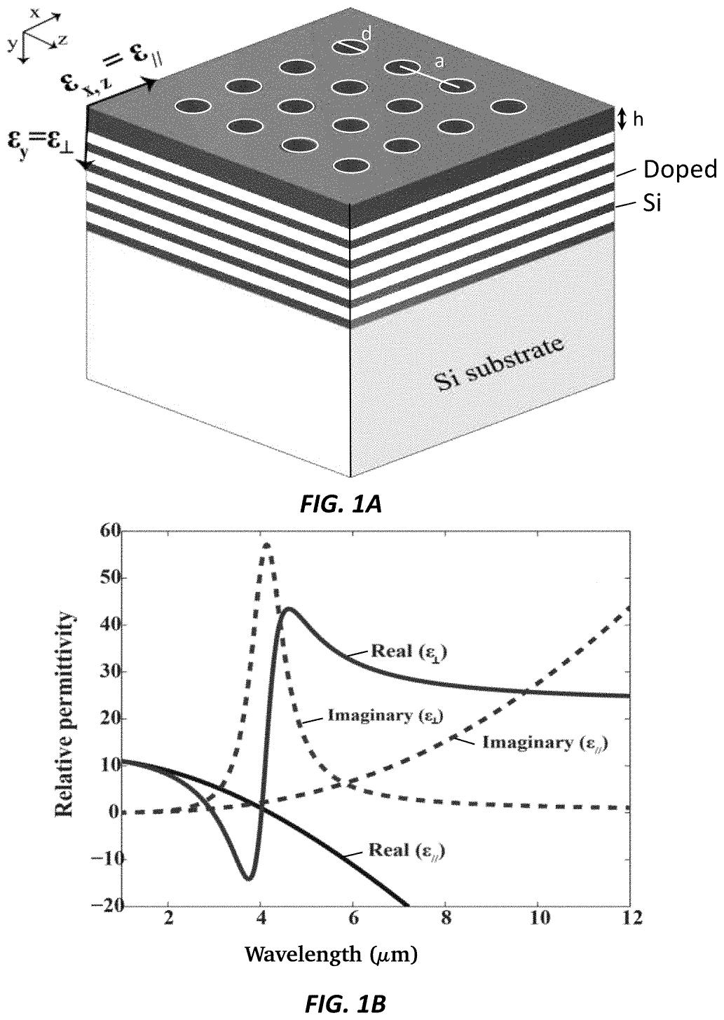

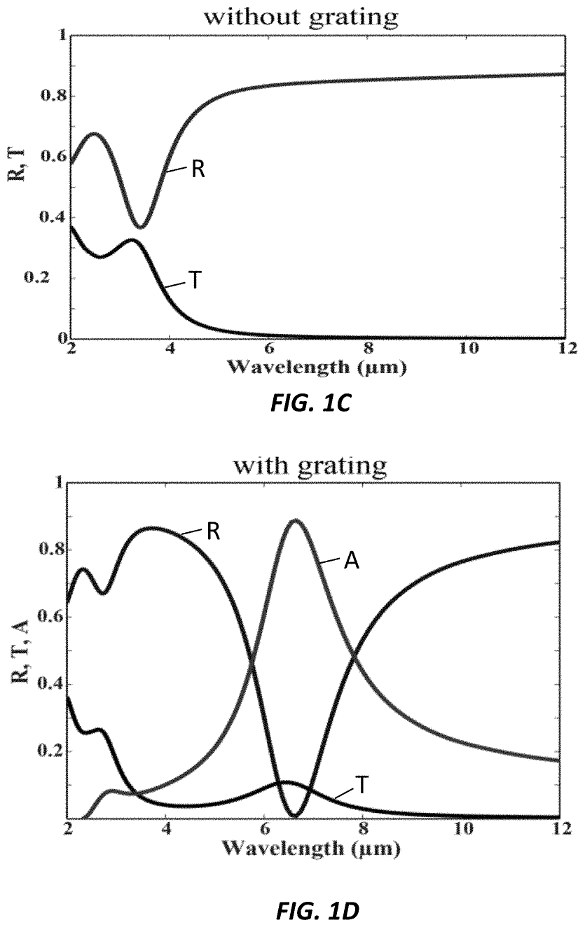

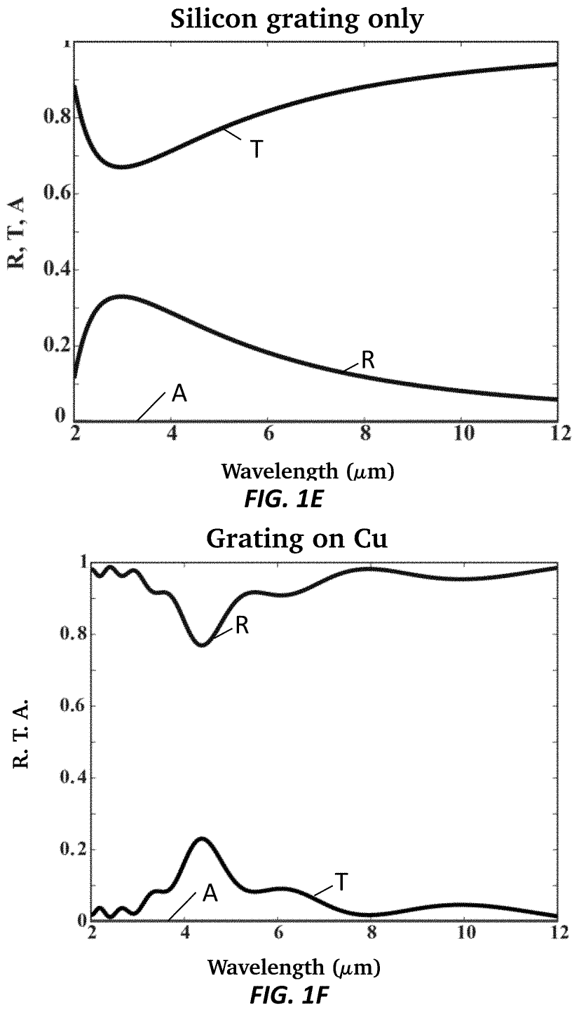

According to one exemplary embodiment, the HMM structure is composed of 10 alternating layers of N-doped silicon acting as metal and silicon acting as dielectric. Negative perpendicular and positive parallel permittivity for the HMM are defined as shown in FIG. 1A. In this example, each layer is of thickness 50 nm and the whole structure is supported on Si substrate, where in other embodiments, the substrate layer includes Ge, GaAs, or InAs. A Si grating of etched holes with height h and diameter d was introduced on top of the HMM with a period of 500 nm. To predict the dispersion behavior of N-doped Si/Si HMM, the effective medium theory (EMT) is used. The effective permittivity in the perpendicular and the parallel directions is given by ε_{⊥}=ε_{y}<0 and ε_{∥}=ε_{X,Z}≥0 respectively.

$$\begin{matrix}{ɛ}_{⊥} = \frac{{ɛ}_{m} {ɛ}_{d}}{{f}_{1} {ɛ}_{m} + {f}_{2} {ɛ}_{d}} & ( 1 ) \\ {ɛ}_{\vert \vert} = {f}_{1} {ɛ}_{m} + {f}_{2} {ɛ}_{d} & ( 2 )\end{matrix}$$

Where εₘ and ε_{d} are the permittivities of N-doped Si and intrinsic Si respectively. f₁ and f₂ are the filling ratios of N-doped silicon and silicon respectively. FIG. 1B shows the hyperbolic dispersion of N-doped Si/Si HMM with type I hyperbolic dispersion (where ε_{⊥}<0 and ε_{∥}>0) for wavelength range 2.9 μm<λ<4.1 μm. Type Π hyperbolic dispersion is shown (where ε_{⊥}>0 and ε_{∥}<0) for wavelength range 4.2 μm<λ<12 μm.

Furthermore, as a step towards simplifying and optimizing the design, the EMT is again applied to study the behavior of the effective sub-hole Si grating (hole dimensions: d=100 nm and h=300 nm) on effective bulk N-doped Si/Si HMM. The effective permittivity for Si with air holes can be expressed by parallel and perpendicular ε_{∥}_{^{grating}} and ε_{⊥}_{^{grating}} respectively.

$$\begin{matrix}{ɛ}_{{\vert \vert}^{grating}} = \frac{( 1 + ρ ) {ɛ}_{air} {ɛ}_{si} + ( 1 - ρ ) {ɛ}_{si}^{2}}{( 1 + ρ ) {ɛ}_{si} + ( 1 - ρ ) {ɛ}_{air}} & ( 3 ) \\ {ɛ}_{⊥ grating} = {ρɛ}_{air} + ( 1 - ρ ) {ɛ}_{si} & ( 4 ) \\ ρ = \frac{{Area}_{hole}}{{Area}_{unitcell}} & ( 5 )\end{matrix}$$

Where εₐᵢᵣ and εₛᵢ are permittivities for air and Si respectively, ρ is the filling ratio, Areaₕₒₗₑ and Area_{unitcell} are the surface area of the hole and the unit cell respectively. FIG. 1C shows simulation results for bulk effective medium of N-doped Si/Si HMM without Si grating (simulated using equations 1 and 2). The absolute reflection (R) is about 0.9 while the absolute transmission (T) is nearly zero. This occurs due to the fact that HMM strongly behaves as metal in the parallel direction where it becomes highly reflective beyond the Brewster angle. In order to calculate the (A) for the following sections, the following formula; A (ω)=1−(R(ω)+T(ω)) is used. FIG. 1D shows R and T for bulk effective medium of N-doped Si/Si HMM loaded with the effective sub-hole Si grating (simulated using equations 3 and 4). It shows that R and T drops significantly while (A) of value 0.9 is observed around wavelength of 6.8 μm. This can be explained as follows: In absence of the grating, the coupling of the incident plane wave into the high propagation K modes of the HMM is impossible. The diffraction grating can however be used as an efficient way to couple the incident light with the high propagation K modes when high order diffraction grating “of order” greater than that of light is applied on HMM. Enhanced wave vector of the grating allows for additional momentum to the incident light where coupling condition can then be satisfied. Once the coupling condition is satisfied, a noticeable resonance occurs leading to high absorption mechanism. In order to confirm that this absorption comes from the grating coupled to HMM. FIG. 1E shows zero absorption both cases of Si grating alone and for Si grating on perfect reflector FIG. 1F.

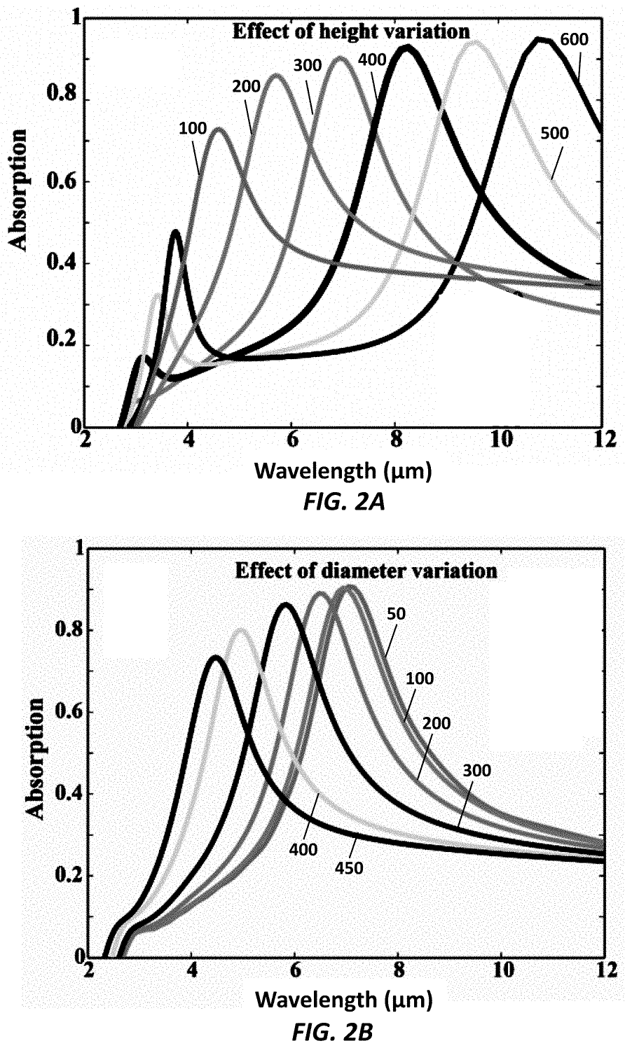

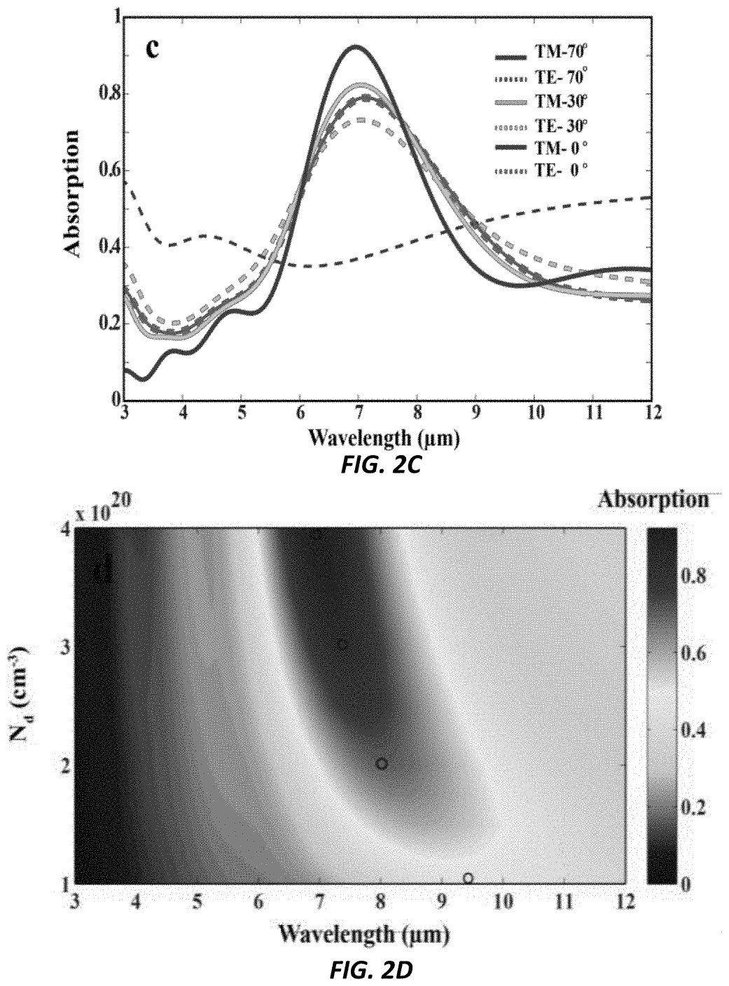

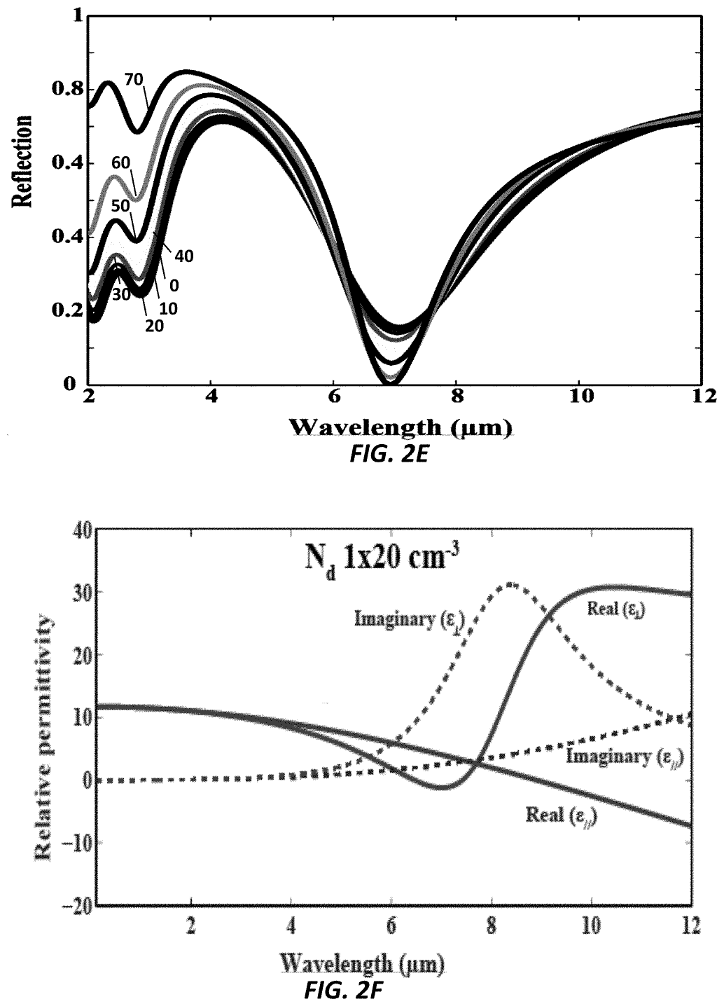

Having now verified the physical mechanism of absorption in the structure of the current invention, presented here is a study in more detail describing the effect of different geometrical aspects of the structure upon its behavior and provided is a clear pathway for designing an efficient CMOS compatible absorber. First, the effect of varying h while keeping d fixed at 100 nm is studied. FIG. 2A shows that increasing h from 100 nm to 600 nm results in red shift of the absorption peak from wavelength 4.5 μm to 11 μm. Absorption varies between 0.72 at wavelength of 4.55 μm to 0.948 at wavelength of 10.75 μm. Increasing h results in larger volume between two corresponding adjacent holes within which the energy gets confined within. The larger volume (for larger heights) will lead to lowering the confined energy and thus the absorption peak will be red shifted.

It could be also seen that the bandwidth of the absorption peak increases slightly at larger wavelengths. This has been demonstrated that the bandwidth of the absorption peak is affected by the contrast in permittivity between the grating and the HMM. The contrast between silicon grating and effective parallel permittivity of the HMM increases at larger wavelengths. FIG. 1B shows that the magnitude of the parallel permittivity increases for larger wavelength with respect to the dielectric permittivity of intrinsic Si (11.7); this explains the slight increase in bandwidth. There is also very good agreement between (A) obtained for height 300 nm at λ=7 μm, shown in FIG. 2A and the same structure studied and demonstrated by EMT in FIG. 1D. This verifies that the EMT works as a good approximation to predict the behavior of our proposed structure. The same effect of tuning the absorption peak can be realized by changing d from 50 nm to 450 nm while h is fixed at 300 nm. FIG. 2B shows that increasing the diameter from 50 nm to 450 nm results in blue shift of the absorption peak from wavelength of 7 μm to wavelength of 4.5 μm. Again, this could be understood in terms of volume where the energy gets confined within. Increasing the hole diameter results in smaller volume between two adjacent hole pillars, therefore, energy confined in smaller volume becomes higher, and thus the absorption peak will be blue shifted. Another key feature in this design is its relative independence over the angle of incidence, a very useful feature for an absorber to acquire. FIG. 2E shows that R drops for all angles from 0 to 70 degrees. The maximum reflection is about 0.17 for normal incidence and near 0 for oblique incidence of angle 70 degrees. In addition, since the grating is periodic in x and z direction, high absorption values can be addressed for TE polarized Light as well. FIG. 2C shows that high absorption values of nearly 0.79 are fulfilled for TE mode which is exactly equal to the TM mode absorption value in case of normal incidence. Increasing the angle of incidence to 30 degrees for TE mode results in slight decrease in absorption compared to the TM mode. Further increase in angle of incidence to 70 degrees reduces the absorption of the TE mode. Generally, 2D grating allows for another degree of freedom while designing polarization less-dependent absorbers. The effect of changing doping concentration (N_{d}) on the absorption peak for grating of dimensions (d=100 nm and h=300 nm) was also studied. FIG. 2D shows that for lower doping concentrations beyond the previously studied doping concentration of (N_{d}=4×10²⁰ cm⁻³), there is a red shift in the absorption band and reduction in absorption value. The black dots in FIG. 2D corresponds to the maximum absorption at four different N_{d} which are; 4×10²⁰, 3×10²⁰, 2×10²⁰, 1×10²⁰ cm⁻³ that results in maximum (A) of 0.92, 0.85, 0.7 and 0.45 respectively. This can be illustrated as follows: decreasing the doping concentration shifts the plasma wavelength for doped Si to larger wavelength. As a consequence, the hyperbolic behavior “which aids the absorption mechanism” will only be supported at longer wavelength as well. FIG. 2F shows the dispersion behavior for the least studied N_{d} of 1×10²⁰ cm⁻³; it is obvious that type H hyperbolic dispersion is realized within wavelength range of 8.2 μm<λ<12 μm (where absorption band is expected to occur). However, in FIG. 2F the perpendicular imaginary part of the permittivity becomes very broad which results in noticeable reduction in absorption to nearly 0.45. Thus, it is important to design the absorber so that the resonance occurs away from hyperbolic regime as shown in the dispersion curve in FIG. 1B.

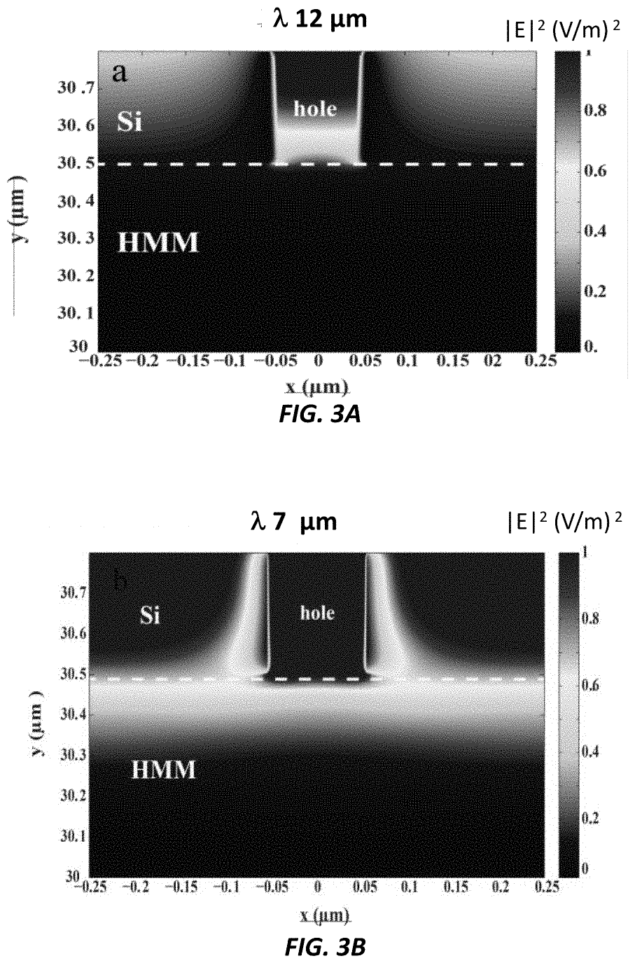

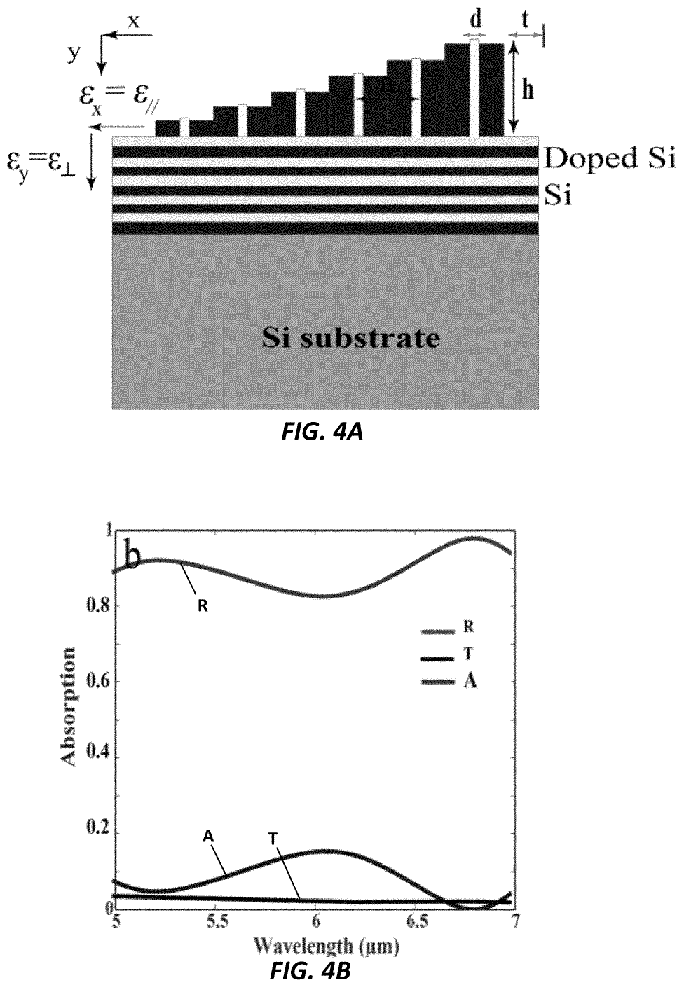

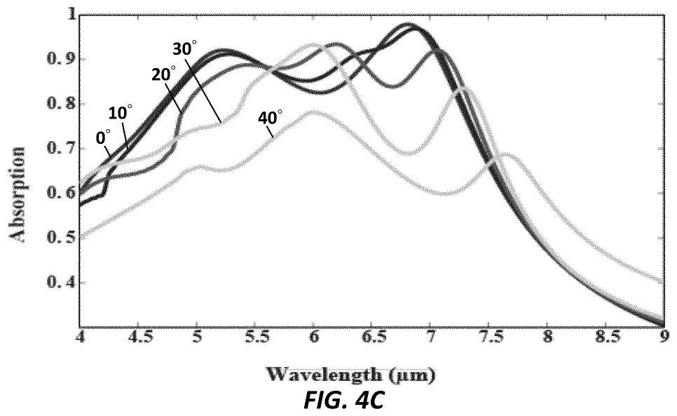

The electric field distribution was simulated for sub-hole Si grating (d=100 and h=300 nm) on N-doped Si/Si HMM. FIGS. 3A-3B show the electric field distribution |E|² for the XY plane for the sub-hole Si grating on N-doped Si/Si HMM. FIG. 3A shows that there is no electric field generated at wavelength of 12 μm in the grating or the HMM. This trend also holds over a wavelength range of 8.5 μm to 12 μm due to the reflective nature of the structure within this range. FIG. 3B shows that electric field confinement in the grating and in the N-doped Si/Si HMM at the resonance wavelength 7 μm as expected. From previous work, it is concluded that depending on the grating dimension absorption within certain wavelength range could be realized. In order to obtain BBA, multiple resonance mechanisms have to be supported at different wavelengths, where perfect coupling between wave vectors of incident light and that for the hyperbolic modes has to be fulfilled. In this section, a unit cell of multi height sub-hole Si Grating (MHSG) was proposed to realize BBA. Each unit cell is composed of six holes of different heights ranging from 100 to 600 nm on the same previously studied N-doped Si/Si HMM as shown in FIG. 4A. The diameter d and period a are fixed at 50 and 500 nm respectively. The spacing between each unit cell and the other is 600 nm. FIG. 4B shows R, T and A for normal TM injection on MHSG N-doped Si/Si HMM. It can be clearly seen that BBA is achieved from 5 μm to 7 μm with (A) varies between 0.83 and 0.97 (minimum and maximum absorption values are selected within the specified wavelength range). The BBA can be achieved at oblique incidence as well as indicated in FIG. 4C.

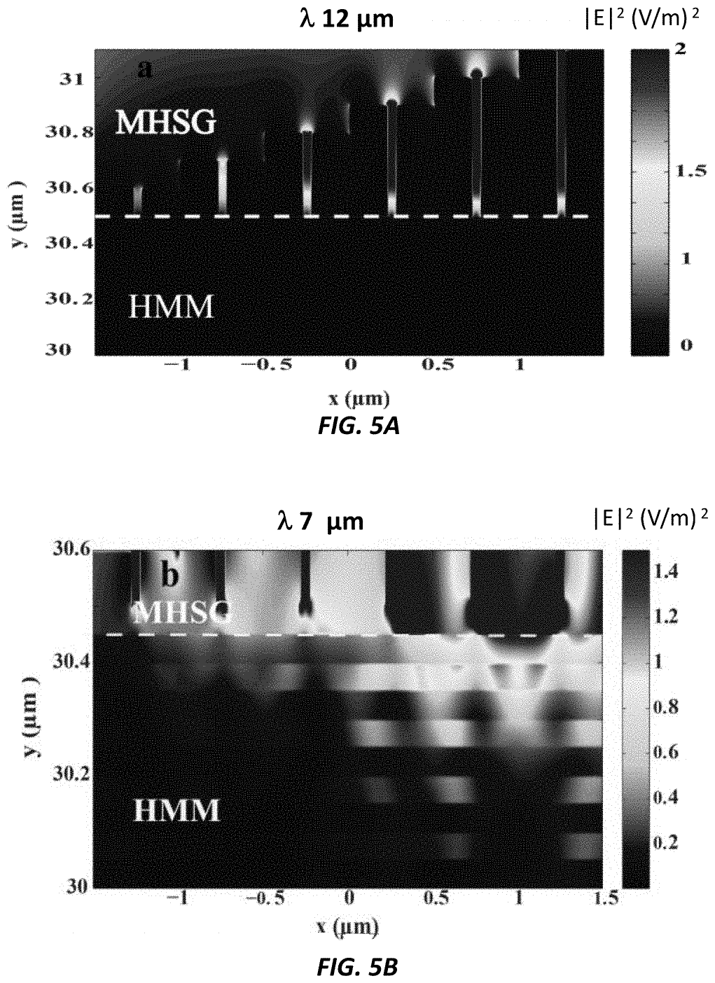

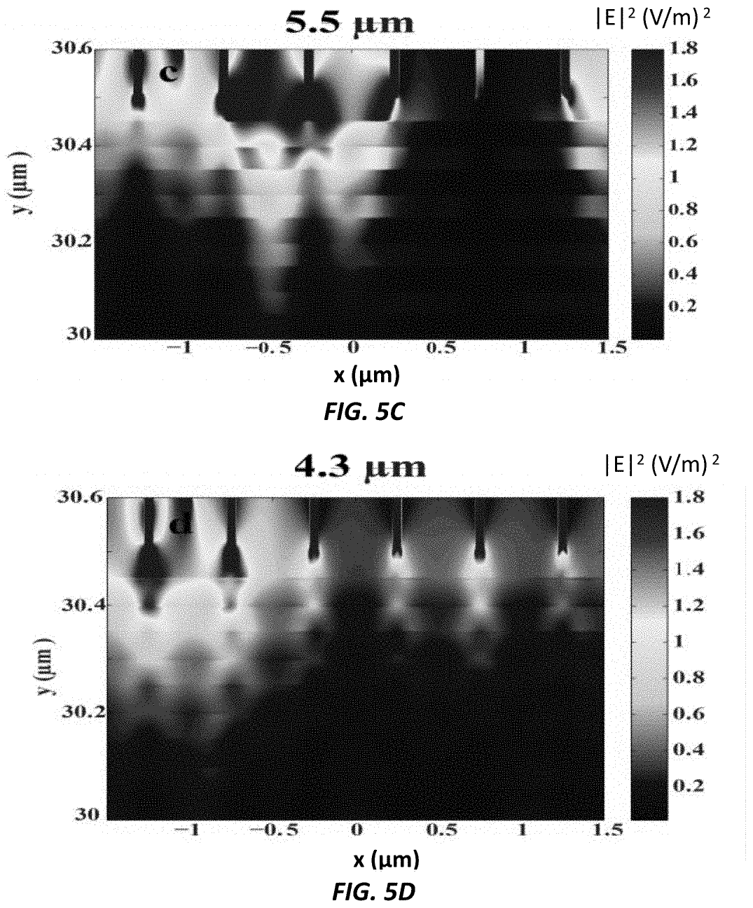

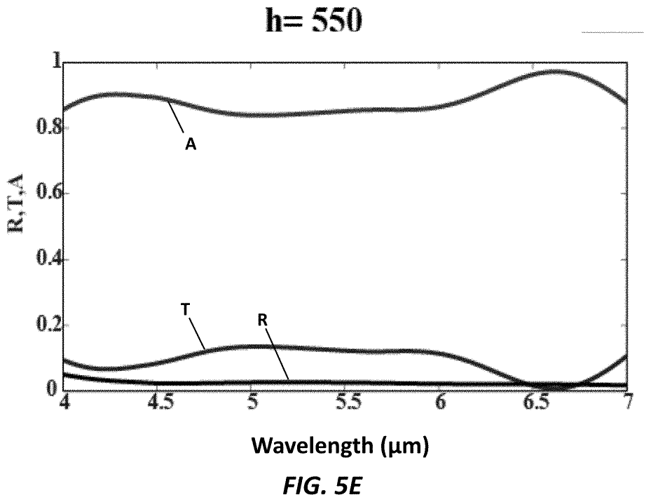

Electric field distribution was simulated for the MHSG N-doped Si/Si HMM structure. FIGS. 5A-5D show the electric field distribution E² at four different spectral regions. FIG. 5A shows that there is no electric field observed at λ of 12 μm since the structure is reflective at λ>8.5 μm. At λ 7 μm, high field confinement is observed in the N-doped Si/Si HMM from sub-holes of h 500 and 600 nm FIG. 5B. Moving to lower wavelength range of 5-6 μm, the mode at the 500 and 600 nm holes start to vanish whilst it appears at the middle sub-holes 200, 300 and 400 nm FIG. 5C. Moving to lower wavelength range 4-5 μm, the mode is realized from the smaller sub-holes 100 and 200 nm FIG. 5D. Below λ of 4 μm, the structure has high T which means it will not serve as good absorber. Generally, photon coupling from air to high K medium can be achieved by using grating coupling network. The quasi periodic designed grating generates quasi periodic guided modes. These modes become resonant at multiple wavelengths when different holes' heights are introduced. These resonating modes cause strong confinement in the HMM and the grating which results in broadband absorption. Worth mentioning here the nature of hyperbolic dispersion of HMMs, the hyperboloid iso-frequency surface is an open/unbounded space which can provide large photonic density of states. The existence of available empty states enhances the incident light coupling mechanism to the doped Si/Si layers surface plasmons and aids the generation of the high lossy guided modes that causes this BBA.

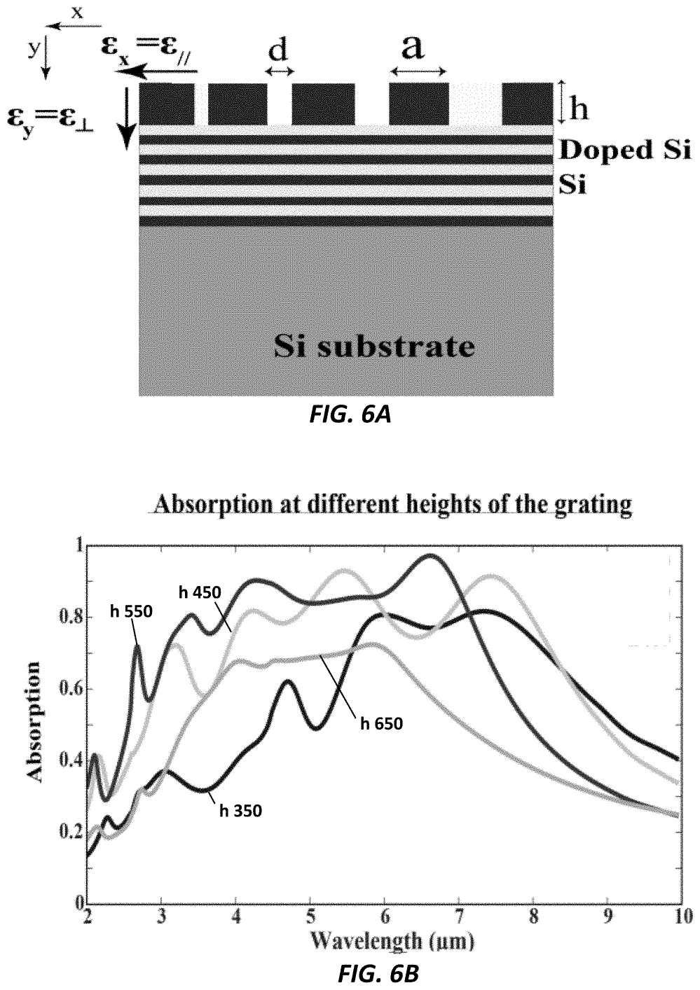

Further presented here is the effect of BBA by proposing a grating design of multiple diameters sub-hole Si grating (MDSG) on N-doped Si/Si HMM. The HMM is typically as previously demonstrated in FIG. 1A and FIG. 4A, the Si grating in this case however include four holes of diameters vary between 100 to 400 nm (FIG. 6A). The height h of the grating is fixed at 550 nm. Dimension a is defined as the distance between two holes and is chosen to be 400 nm. FIG. 5E shows that BBA could be realized from wavelength 4.5 μm to 7 μm where (A) varies between 0.84-0.972.

FIG. 6B indicates the shifts in absorption band for different grating heights for the same studied MDSG. For grating of height 650 nm, the BBA is realized within the wavelength range of (3.7 μm to 6 μm) while the (A) is nearly (0.6 to 0.71). For grating of height 550 nm, the BBA is realized within the wavelength range of (2.9 μm to 7.4 μm). Reducing the grating height to 450 nm shifts the BBA to 8.3 μm while the (A) is slightly decreased. Further reduction in grating height to 350 nm shifts the BBA to nearly (5.5 μm to 8.3 μm) while (A) is reduced to nearly (0.67 to 0.8). It is obvious that, there is a slight red shift in the BBA when the height of the grating decreases from 650 to 350 nm and this contradicts our previous analysis. It was previously explained that for periodic grating of fixed height, decreasing the height results in blue shift in the absorption peak (FIG. 2A) since decreasing the volume of confinement increases the confined energy and thus results in a blue shift.

However, in the case of multi diameters Si grating structure, it is acknowledged that the fact that this system is a quasi-periodic system and its physics is much more complex than the previous single dimension hole grating. In such complex design, the interaction or interference effect of each sub-hole with one another should be considered.

In this disclosure, demonstrated is a mid-IR Si based super absorber of total thickness not exceeding 1 microns using HMM integrated with sub-hole Si grating. Single band absorption was achievable with (A) reaching 0.948. The absorption peak is able to be tuned over the mid-IR range from 4.5 to 11 μm by either changing the grating hole's height or by changing the hole's diameter. Confirmed herein is an omnidirectional and less-polarization dependent absorber. The first proposed design has profound application in bio and chemical sensing mechanisms based upon tuning the single absorption peak of predesigned grating. It was shown that BBA can be achieved by using an all Si based structure. Further shown are two grating designs, namely: Si grating with different holes' height and Si grating with different holes' diameter, both were integrated with the N-doped Si/Si HMM. Both designs have acquired BBA with maximum (A) reaching 0.97. In order to maximize the band width of the broadband absorption, further studies will be required to understand the interaction between sub-holes with one another. In addition, in order to confirm that these resonating modes are due to the fact of excitation of BPPs in HMM, a study on the electron distribution complex profile in HMM is a must. Precise identification of the bulk plasmons location based upon studying the electron distribution allows for the dispersion relation of bulk plasmons in doped semiconductor/semiconductor HMM. This can be done as a whole study on bulk plasmons in complex structures in a future work. It should be accounted also that the effective medium approximation does not take into consideration the interaction among sub-wavelength structures within the single unit cell, it is an approximation for a whole sub-wavelength periodic system. The broadband absorbers of the current invention are suitable candidates for thermal harvesting application in the mid IR range. An additional advantage for the structure is that it is an all Si based absorber which consequently indicates the feasibility of being fabricated by standard Si fabrication techniques. For metamaterial fabrication, standard chemical vapor deposition can be applied for Si layers deposition while ion beam irradiation can be used to dope the Si layers. For patterning both the periodic grating or the multiple diameters' hole grating, photolithography and deep reactive ion etching can be used. For grating of different hole heights', nano imprint lithography can be used to pattern a stair case grating followed by photolithography and deep reactive ion etching. This absorber opens avenues for CMOS compatible energy harvesters for on chip purposes.

Finite difference time domain is used for simulating a TM polarized Plane wave incident from the top of the proposed structure. Perfect matched layer (PML) is defined along the y directions whereas Bloch Boundary conditions are defined along the x and z directions.

The permittivity of N-doped Si ε_{doped} at certain dopant concentration N_{d} is calculated using Drude model as follows:

$${ɛ}_{doped} = {ɛ}_{∞} - \frac{{ω}_{p}^{2}}{{ω}^{2} + i ωΓ}$$

Where ωₚ is the plasma frequency, ε_{∞} is the static frequency, Γ is the damping term, m* is the effective mass, q is the electronic charge. N_{d} was taken to be 4×10²⁰ cm⁻³ which yields plasma wavelength of 2.9 μm.

The present invention has now been described in accordance with several exemplary embodiments, which are intended to be illustrative in all aspects, rather than restrictive. Thus, the present invention is capable of many variations in detailed implementation, which may be derived from the description contained herein by a person of ordinary skill in the art. For example the whole structure can be scaled to different wave length range based on the doping concentration of Si employed in Si and operates as an absorber across different wavelengths within the IR regime. All such variations are considered to be within the scope and spirit of the present invention as defined by the following claims and their legal equivalents.

What is claimed:

1) A broadband hyperbolic metamaterial absorber, comprising:
a) a substrate layer;
b) a plurality of N-doped silicon layers;
c) a plurality of silicon layers; and
d) a silicon grating layer, wherein said silicon grating layer comprises a pattern of through-holes, wherein said through-holes have a diameter d, a height h, and a periodic separation distance a;
wherein said plurality of N-doped silicon layers and said plurality of silicon layers are arranged in a stack of alternating layers of said N-doped silicon layers and said silicon layers disposed on said substrate layer, wherein said silicon grating layer is disposed on said stack of alternating layers of said N-doped silicon layers and said silicon layers.

2) The broadband hyperbolic metamaterial absorber of claim 1, wherein said through-hole diameter d has a size in a range of 100 nm to 400 nm while a and h are fixed.

3) The broadband hyperbolic metamaterial absorber of claim 1, wherein said through-hole height h has a size in a range of 100 nm to 600 nm while d and a are fixed.

4) The broadband hyperbolic metamaterial absorber of claim 1, wherein said substrate layer comprises a material selected from the group consisting of silicon, Ge, GaAs, and InAs.

5) The broadband hyperbolic metamaterial absorber of claim 1, wherein an absorption (A) of 0.95 is within a Mid IR wave length range from 3-8 μm.
